(19) United States
(12) Patent Application Publication
(10) Pub. No.: US 2004/0204192 A1
(43) Pub. Date: Oct. 14, 2004

(54) Automobile dashboard display interface for facilitating the interactive operator input/output for a standard wireless telephone detachably mounted in the automobile

(75) Inventors: Lane Thomas Holloway, Pflugerville, TX (US); Marques Benjamin Quiller, Pflugerville, TX (US)

Correspondence Address: Mark E. McBurney, International Business Machines Corporation, Intellectual Property Law Dept., Internal Zip 4054, 11400 Burnet Road, Austin, TX, 78758, US

(73) Assignee: International Business Machines Corporation, Armonk, NY (US)

(21) Appl. No.: 10/232,252

(22) Filed: Aug. 29, 2002

(51) Int. Cl. H04B 1/06; H05K 11/02; H04M 1/00; H04B 1/38

(52) U.S. Cl. 455/575.1; 455/346; 455/566

(57) ABSTRACT

An arrangement whereby the standard wireless telephone can still retain all of its desirable light weight and size features while detached from and out of the automobile while still providing user interfaces with a minimum of distraction from driving while the wireless telephone is functionally attached within the automobile. There is a housing adjacent the dashboard for detachably receiving a separable wireless telephone with a display smaller than said dashboard display in combination with switching apparatus for bypassing the wireless telephone display with said dashboard display when said wireless telephone is received in said housing whereby the dashboard display functions as the wireless telephone display. The system may be set so that the switching apparatus automatically bypasses said wireless telephone display when said wireless telephone is inserted into said housing. The standard transceiver in the wireless cellular telephone continues to function normally in receiving and transmitting communications even when the telephone display is bypassed by the dashboard display. This arrangement gives the operator the benefit of having the numerals, text and other elements presented on the dashboard display enlarged from their normal size on the wireless telephone display.

### TECHNICAL FIELD

The present invention relates to the use of wireless telephones in automobiles, and particularly to improving such use under circumstances presenting safety hazards.

### BACKGROUND OF RELATED ART

With the globalization of business, industry and trade wherein transactions and activities within these fields have been changing from localized organizations to diverse transactions over the face of the world, the telecommunication industries have, accordingly, been expanding rapidly. Wireless telephones and, particularly, cellular telephones have become so pervasive that their world wide number is fast approaching hundreds of millions. While the embodiment to be subsequently described relates to cellular telephones, the principles of the invention would be applicable to any wireless personal communication device that could be used to communicate from the inside of an automobile. These would include the wide variety of currently available communicating personal palm devices or Personal Digital Assistants (PDAs), which include, for example, Microsoft's WinCE line; the PalmPilot line produced by 3Com Corp.; and International Business Machines Corporation's WorkPad. These devices are comprehensively described in the text, Palm III & PalmPilot, Jeff Carlson, Peachpit Press, 1998.

Unfortunately, the use of wireless telephones by drivers of automobiles has been related to an increasing number of automobile accidents. The cellular phone not only requires the use of one or even both of the driver's hands, but also diverts the driver's attention from driving. The problem has become so pronounced that many states and countries have enacted or are considering the enactment of legislation banning the use of cell phones by drivers in moving vehicles. Such legislation has been opposed by many who regard it as too intrusive on drivers, as well as too difficult to enforce. However, the problem may be expected to become more pronounced along with the progress of the philosophy of the mobile office where the worker is available “24 hours a day—seven days a week”.

Consequently, the wireless telephone, as well as the automotive industries are seeking solutions to these problems for drivers. A significant source of the safety problem of the wireless telephone in automobiles has been the miniaturization of the standard wireless telephone, the cellular phone. In order to make the telephone as light in weight as possible, all input/output functions including display and manual inputs are miniature. Of course, under driving conditions, considerable attention has to be diverted from driving to deal with such miniatures. As a result, it has become illegal in most jurisdictions to use a wireless telephone requiring use of hands while driving. Such laws require the automobile operator to pull off the road and stop before using the telephone. Unfortunately, such traffic laws are continuously disobeyed by a relatively high number of drivers. The problem is greatest with incoming wireless calls. Even drivers who are inclined to stop their automobile in order to make an outgoing call, will on the whole divert attention and juggle with the telephone to deal with the miniaturization just to determine whether the incoming call is important enough to pull off the road for.

### SUMMARY OF THE PRESENT INVENTION

The present invention offers a solution to the above-described problems of cell phone use during driving. It involves the recognition that despite traffic laws to the contrary, drivers will still need to relate to at least incoming wireless telephone calls while driving. Accordingly, it provides an arrangement whereby the standard wireless telephone can still retain all of its desirable light weight and size features, detached from and out of the automobile while still providing user interfaces with a minimum of distraction from driving while the wireless telephone is functionally attached within the automobile.

Accordingly, the present invention provides a system for facilitating input/output from the automobile in wireless telephone communications from an automobile with a computer controlled operator interactive dashboard display. There is a housing adjacent the dashboard for detachably receiving a separable wireless telephone with a display smaller than said dashboard display in combination with switching apparatus for bypassing the wireless telephone display with said dashboard display when said wireless telephone is received in said housing whereby the dashboard display functions as the wireless telephone display. The system may be set so that the switching apparatus automatically bypasses said wireless telephone display when said wireless telephone is inserted into said housing. The standard transceiver in the wireless cellular telephone continues to function normally in receiving and transmitting communications even when the telephone display is bypassed by the dashboard display. This arrangement gives the operator the benefit of having the numerals, text and other elements presented on the dashboard display enlarged from their normal size on the wireless telephone display. This makes it easier for the operator of the automobile to quickly discern incoming data with minimum distraction from his driving.

In addition, the automobile control system may optionally be set up to bypass the wireless telephone audio speaker with the automobile audio speaker system when said wireless telephone is received in said housing whereby the automobile audio speaker system functions as the wireless telephone audio speaker system. Likewise, the control system may also be set up to bypass the wireless telephone input/output with the automobile input/output interface when said wireless telephone is received in said housing whereby the automobile input/output interface functions as the wireless telephone input/output interface. Here again, the automobile I/O is likely to have larger elements with better human factors than the wireless telephone I/O/.

### BRIEF DESCRIPTION OF THE DRAWINGS

The present invention will be better understood and its numerous objects and advantages will become more apparent to those skilled in the art by reference to the following drawings, in conjunction with the accompanying specification, in which:

FIG. 1 is a block diagram of a generalized data processing system including a central processor unit that provides an illustration of the on-board automobile operations control system for receiving the wireless telephone and for bypassing the display and optionally other I/Os of the wireless telephone with corresponding I/Os of the automobile whenever the wireless telephone is mounted in the automobile;

FIG. 2 is an illustration of the various components in a cellular telephone that is detachably mounted in the automobile, as well as the housing in the automobile for receiving the wireless cellular telephone;

FIG. 3 is an illustrative flowchart describing the setting up of the elements needed for the program of the invention for the receiving of cellular wireless telephones and the bypassing of the display and optionally other I/Os of the wireless telephone with corresponding I/Os of the automobile whenever the wireless telephone is mounted in the automobile;

FIG. 4 is a flowchart of an illustrative simplified run of the program set up in FIG. 3; and

FIG. 5 is an illustrative front view of an automobile dashboard set up in accordance with the invention to illustrate the sizes and spatial relationship between the elements.

### DETAILED DESCRIPTION OF THE PREFERRED EMBODIMENT

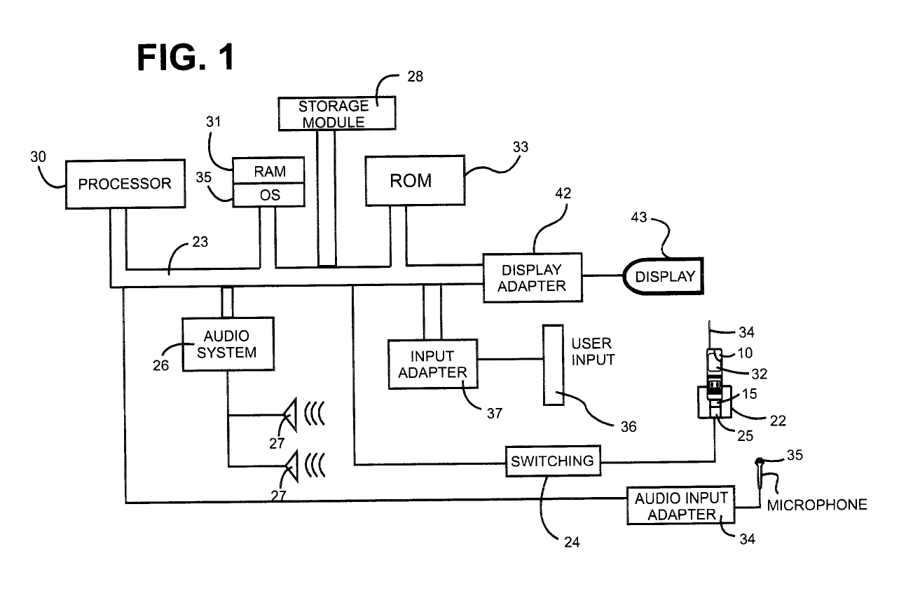

Referring to FIG. 1, there is provided a diagrammatic view of a typical computer control system that may function to control and combine the elements of this invention. Central processing unit 30, which controls the various functions to be described, is interconnected to various other components by system bus 23. An operating system 35 that runs on processor 30 provides control and is used to coordinate the functions of the various components of the control system. The OS 35 is stored in Random Access Memory (RAM) 31, which, in a typical automobile control system, has from four to eight megabytes of memory. The programs for the various automobile monitor and control functions, including those of the present invention, are permanently stored in Read Only Memory (ROM) 33 and moved into and out of RAM to perform their respective functions. The automobile has a basic display 43 controlled through display adapter 42 to provide information to the driver. This will function as the wireless telephone display when the smaller telephone display is bypassed, as will be hereinafter described. The automobile operator may provide interactive commands to the automobile control system through a user input 36 that may conveniently be implemented by standard dashboard buttons connected via an appropriate input adapter 37. Information on control functions is stored in a central storage unit 28 where it is available for diagnostics and related purposes.

As will be seen hereinafter in greater detail, housing 22, usually positioned within reach of the operator, is set up to detachably seat or receive any conventional wireless telephone 32 having a display screen 10, antenna 34 and contact set 15. Housing 22 has a contact set 25 that coincides with telephone contact set 15. The wireless telephone may be any standard cell phone. If the respective contact sets do not coincide, suitable adapters may be inserted into housing 22 to insure the coincidence of the contacts. Accordingly, in the simplest arrangement, cellular telephone 32 functions normally until it is seated in housing 22. When the two sets of contacts 15 and 25 meet, a signal is sent to switching center 24, which, under the control of processor 30, short-circuits or bypasses the miniature telephone display 10 with a path to the larger dashboard display 43, and all incoming data to the telephone 32 is displayed on the larger dashboard display 43.

The combination may be set up so that only the display is thus bypassed; all other wireless telephone functions continue normally. The receiving and sending of telephonic communications continues normally, as does the telephone's input/output and sound systems. The automobile designers may not wish to encourage use of the phone for outgoing calls while driving. Thus, the enlarged display alone will permit the driver to determine whether or not he wishes to pull over and take the call. On the other hand, the automobile may optionally be designed so that when the wireless phone 32 is seated, the switching center 24 under processor 30 control also bypasses the telephone speakers and microphone with the automobile's audio system 26 controlling speakers 27, as well as with input microphone 35 through input adapter 34. Likewise, the telephone's key input device may be bypassed via switching center to the automobile's operator input 36.

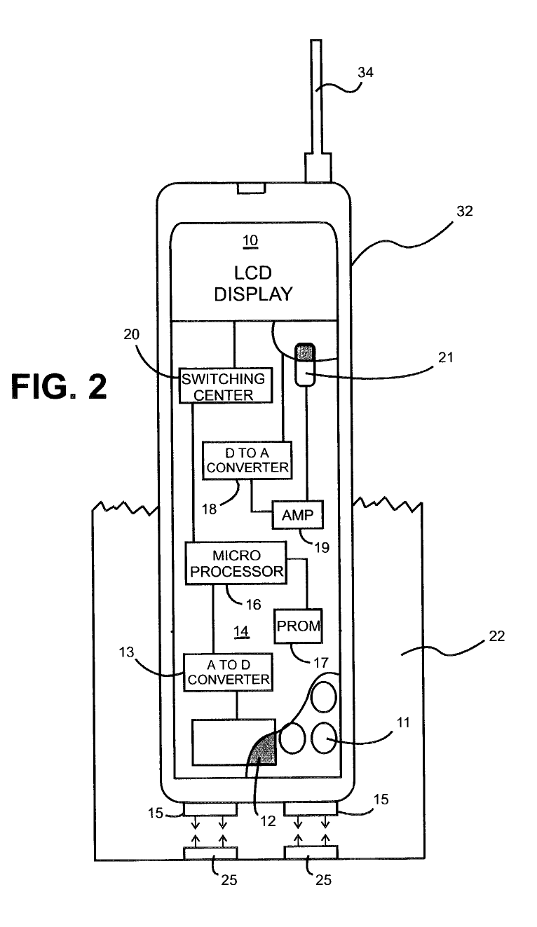

With reference to FIG. 2, there will now be described a typical wireless cellular telephone equipped with switching means permitting the automobile system to bypass the display and other I/O phone functions. As previously described, the wireless telephone 32 has antenna 34 through which it communicates conventionally with cellular telephone system cell towers. This communication operates in an unchanged conventional manner irrespective of the bypassing of the I/O functions. Telephone is dropped into or removed from housing 22 in the directions shown by the arrows. When the contacts 15 and 25 meet, the switching takes place in the automobile as previously described. Otherwise, the cellular telephone operates in its conventional manner.

Signals to antenna 34 are connected to D to A converter 18 to convert received RF digital signals from the cell area station tower into analog signals that are amplified through amplifier 19 and input to speaker 21. Conversely, spoken words into microphone 12 provide an analog signal that is converted into a digital signal in A to D converter 13 and fed to antenna 34 that broadcasts the digital signal to a cell area station tower. The wireless telephone also has an LCD display 10 and input keys 11. The telephone member also has a switching center 20, which, under the control of microprocessor 16, switches when the telephone contacts are seated in the housing to bypass at least display 10 with the automobile's display or, optionally, also bypasses speaker 21, microphone 12 and input keys 11 with the automobile's corresponding systems as previously described. The processing and housekeeping functions within the cellular telephone are controlled by microprocessor 16 supported by a PROM memory 17.

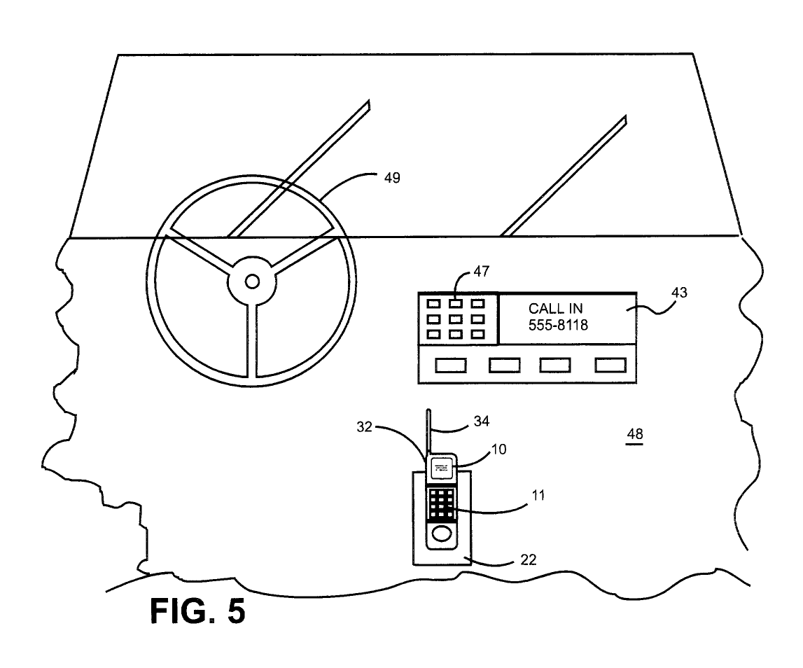

FIG. 5 is included as illustrative of the effective results of the invention. In an automobile dashboard 48 associated with steering wheel 49, there is display 43 and associated input keys 47. Nearby, is housing 22 with received cellular telephone 32, the display 10 of which has been bypassed by dashboard display 43. Based on the comparative sizes of the displays, it may be seen that the identifying number of an incoming telephone call that would be a distraction to read on miniature display 10 of the telephone is easy to read on the larger automobile display 43.

Because any conventional wireless telephone in any conventional wireless telephone system may be adapted to the present invention while the mode of the wireless transmission would continue to operate in its standard manner, it is not necessary to illustrate the details of any particular wireless transmission system. However, since the illustrative example is using a wireless cellular telephone system, some background is deemed to be appropriate. In the cellular system for the handheld mobile wireless phone, an area such as a city is broken up into small area cells. Each cell is about 10 square miles in area. Each has its base station that has a tower for receiving/transmitting and a base connected into PSTN. Even though a typical carrier is allotted about 800 frequency channels, the creation of the cells permit extensive frequency reuse so that tens of thousands of people in the city can be using their cell phones simultaneously. Cell phone systems are now preferably digital with each cell having over 160 available channels for assignment to users. In a large city there may be hundreds of cells, each with its tower and base station. Because of the number of towers and users per carrier, each carrier has a Mobile Telephone Switching Office (MTSO) that controls all of the base stations in the city or region and controls all of the connections to the land based PSTN. When a client cell phone gets an incoming call, MTSO tries to locate what cell the client mobile phone is in. The MTSO then assigns a frequency pair for the call to the cell phone. The MTSO then communicates with the client over a control channel to tell the client or user what frequency channels to use. Once the user phone and its respective cell tower are connected, the call is on between the cell phone and tower via two way long range RF communication. In the United States, cell phones are assigned frequencies in the 824-894 MHz ranges. Since transmissions between the cell telephone and cell tower are digital, but the speaker and microphone in the telephone are analog, the cell telephone has to have a D to A converter from the input to the phone speaker, and an A to D converter from the microphone to the output to the cell tower.

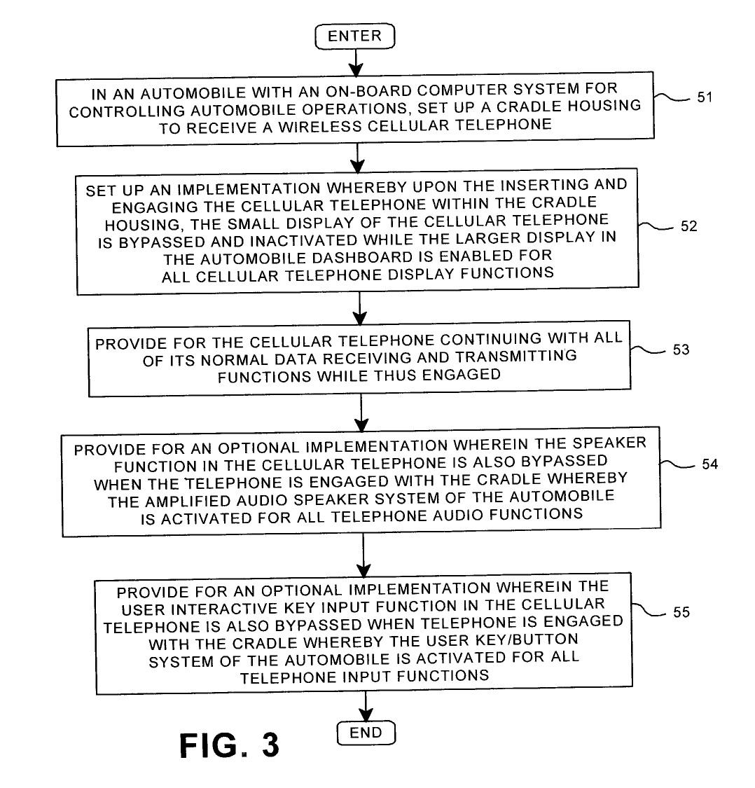

Now, with reference to the programming shown in FIG. 3, there will be described how the system and programs of the present invention are set up. In an automobile having a standard on-board computer system for controlling automobile operations, there is set up a cradle housing for receiving a wireless cellular telephone, step 51. An implementation is provided whereby upon the inserting and engaging of the cellular telephone within the cradle housing, the small display of the cellular telephone is bypassed and thereby inactivated while the larger display in the automobile dashboard is enabled for all cellular telephone display functions, step 52. Otherwise, it is provided that the cellular telephone will continue with all its normal data receiving and transmitting functions while thus engaged, step 53. Also, an optional implementation is provided wherein the speaker function in the cellular phone is engaged with the cradle whereby the amplified audio speaker system of the automobile is activated for all telephone audio functions, step 54. In addition, there is provided an optional implementation wherein the user interactive key input function in the cellular telephone is also bypassed when the telephone is engaged with the cradle whereby the user key/button entry of the automobile is activated for all telephone input functions, step 55.

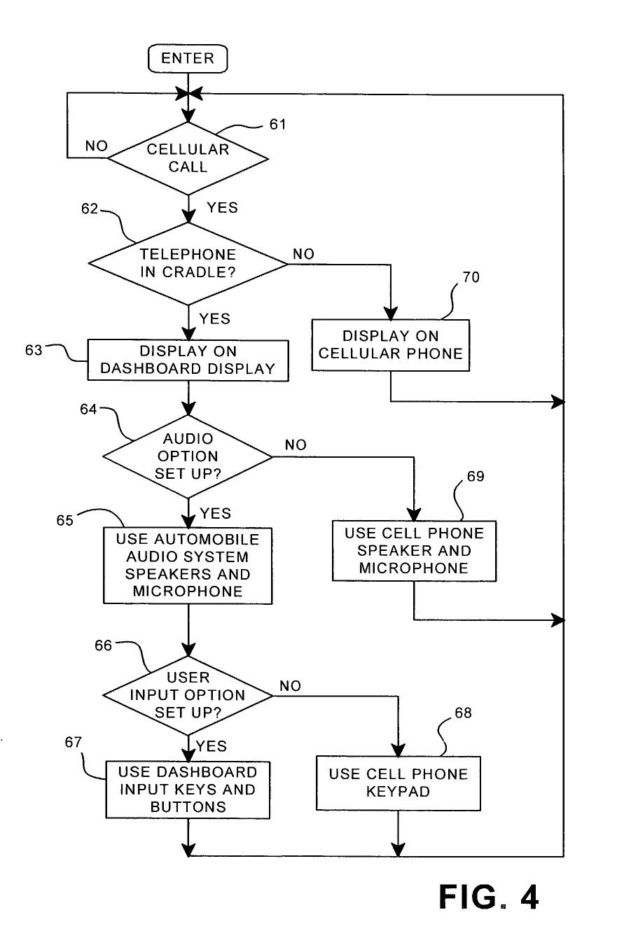

Now, with reference to the flowchart of FIG. 4, a simplified illustrative run of the process set up in FIG. 3 will be described. A determination is made as to whether there is a cellular telephone call being made, step 61. If Yes, a determination is then made as to whether the cell phone is seated in its cradle, step 62. If No, the display is operated normally on the telephone display, step 70. If Yes, the telephone display is bypassed and the data to be displayed is shown on the automobile dashboard display, step 63, after which there is an additional determination as to whether the optional audio bypass has also been set up, step 64. If No, the telephone speaker and microphone is used normally, step 69. If Yes, the telephone audio system, speakers and microphone, are bypassed and the automobile's speaker and microphone system are used, step 65. Next, a further determination is made as to whether the option of using the automobile's I/O has been set up, step 66. If No, the telephone's key pad is used for I/O. If Yes, the telephone's key pad is bypassed and the automobile dashboard keys and buttons are activated for I/O. At this point, the current status of I/Os is continued as long as the telephone call continues as determined in step 61.

Although certain preferred embodiments have been shown and described, it will be understood that many changes and modifications may be made therein without departing from the scope and intent of the appended claims.

What is claimed is:

1. In an automobile with a computer controlled operator interactive dashboard display, a system for facilitating input/output from the automobile in wireless telephone communications comprising:
a housing for detachably receiving a separable wireless telephone with a display smaller than said dashboard display; and
switching apparatus for bypassing the wireless telephone display with said dashboard display when said wireless telephone is received in said housing whereby the dashboard display functions as the wireless telephone display.

2. The system of facilitating wireless communications from an automobile of claim 1 wherein said switching apparatus automatically bypasses said wireless telephone display when said wireless telephone is inserted into said housing.

3. The system of facilitating wireless communications from an automobile of claim 2 wherein said wireless telephone includes a transceiver that continues to function normally in receiving and transmitting communications when the telephone display is bypassed by the dashboard display.

4. The system of facilitating wireless communications from an automobile of claim 3 wherein elements presented on the dashboard display are enlarged from their normal size on the wireless telephone display.

5. The automobile of claim 3 further including:
an audio speaker system with input/output through said dashboard display; and
apparatus for bypassing the wireless telephone audio speaker with the automobile audio speaker system when said wireless telephone is received in said housing whereby the automobile audio speaker system functions as the wireless telephone audio speaker system.

6. The automobile of claim 3 further including:
an input/output interface through said dashboard display; and
apparatus for bypassing the wireless telephone input/output with the automobile input/output interface when said wireless telephone is received in said housing whereby the automobile input/output interface functions as the wireless telephone input/output interface.

7. The system of facilitating wireless communications from an automobile of claim 3 wherein said wireless telephone is a cellular wireless telephone transmitting and receiving in a wireless telephone system.

8. In an automobile with a computer controlled operator interactive dashboard display, a method for facilitating input/output from the automobile in wireless telephone communications comprising:
detachably receiving with said automobile a separable wireless telephone with a display smaller than said dashboard display; and
bypassing the wireless telephone display with said dashboard display when said wireless telephone is received whereby the dashboard display functions as the wireless telephone display.

9. The method of facilitating wireless communications from an automobile of claim 8 wherein said wireless telephone display is automatically bypassed when said wireless telephone is inserted into said housing.

10. The method of facilitating wireless communications from an automobile of claim 9 wherein said wireless telephone continues to function normally in receiving and transmitting communications when the telephone display is bypassed by the dashboard display.

11. The method of facilitating wireless communications from an automobile of claim 10 including the step of enlarging elements presented on the dashboard display from their normal size on the wireless telephone display.

12. The method of facilitating wireless communications from an automobile of claim 10 further including the step of bypassing the wireless telephone audio speaker with the automobile audio speaker when said wireless telephone is received in said automobile whereby the automobile audio speaker system functions as the wireless telephone audio speaker system.

13. The method of facilitating wireless communications from an automobile of claim 10 further including the step of bypassing the wireless telephone input/output with the automobile input/output interface when said wireless telephone is received in said automobile whereby the automobile input/output interface functions as the wireless telephone input/output interface.

14. The method of facilitating wireless communications from an automobile of claim 10 wherein said wireless telephone is a cellular wireless telephone transmits and receives by a wireless cellular telephone method.

15. A computer program having code recorded on a computer readable medium for facilitating input/output wireless telephone communications from the automobile with a dashboard display comprising:
means in said automobile for detachably receiving a separable wireless telephone with a display smaller than said dashboard display; and
means for bypassing the wireless telephone display with said dashboard display when said wireless telephone is received in said receiving means whereby the dashboard display functions as the wireless telephone display.

16. The computer program of claim 15 wherein said means for bypassing automatically bypasses said wireless telephone display when said wireless telephone is inserted into said receiving means.

17. The computer program of claim 16 wherein said wireless telephone includes a transceiver that continues to function normally in receiving and transmitting communications when the telephone display is bypassed by the dashboard display.

18. The computer program of claim 17 wherein elements presented on the dashboard display are enlarged from their normal size on the wireless telephone display.

19. The computer program of claim 17 wherein said automobile includes an audio speaker system with input/output through said dashboard display; and
said program further includes means for bypassing the wireless telephone audio speaker with the automobile audio speaker system when said wireless telephone is inserted into said receiving means whereby the automobile audio speaker system functions as the wireless telephone audio speaker system.

20. The computer program of claim 3 wherein said wireless telephone is a cellular wireless telephone transmitting and receiving in a wireless telephone system.
